(19) United States
(12) Patent Application Publication
(10) Pub. No.: US 2008/0121414 A1
(43) Pub. Date: May 29, 2008

(54) Printed circuit board and method for manufacturing thereof

(75) Inventors: Eung-Suek Lee, Ansan-si (KR); Dek-Gin Yang, Cheongwon-gun (KR); Keun-Ho Kim, Seo-gu (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 11/812,661

(22) Filed: Jun. 20, 2007

(30) Foreign Application Priority Data
Jun. 21, 2006 (KR) 10-2006-0055844

(51) Int. Cl. H05K 1/05; H05K 3/10

(52) U.S. Cl. 174/252; 29/846

(57) ABSTRACT

A printed circuit board and a method of manufacturing thereof are disclosed. With a printed circuit board comprising an insulating layer; a circuit pattern formed on one side of the insulating layer; an inter-layer conductive part joining with the insulating layer by passing through the insulating layer, and electrically connected to the circuit pattern; a heat dissipating layer laminated on the other side of the insulating layer; and a heat dissipating coating layer interposed between the insulating layer and the heat dissipating layer, and connected with the inter-layer conductive part, the heat contained in the insulating layer may be delivered to the heat dissipating layer effectively and the efficiency of heat dissipation may be improved.

### CROSS-REFERENCE TO RELATED APPLICATIONS

This application claims the benefit of Korean Patent Application No. 10-2006-0055844 filed with the Korean Intellectual Property Office on Jun. 21, 2006, the disclosure of which is incorporated herein by reference in its entirety.

### BACKGROUND

1. Technical Field

The present invention relates to a printed circuit board and a method for manufacturing thereof.

2. Description of the Related Art

Presently, as electronic products are becoming thinner and given more functionalities, a greater number of passive elements and higher density and multi layer packages are being mounted in a printed circuit board (PCB). This trend is expected to continue in the future. On a basic level, the printed circuit board has performed the role of connecting various kinds of electronic elements or supporting components according to the design of circuit patterns. However, as the number of passive elements and packages mounted in the PCB is increased, so also are the amount of power consumption and the amount of heat generated, whereby the efficiency of heat dissipation is becoming an important decision criterion in terms of reliability and consumer preferences. Thus, there is a demand for a functional printed circuit board which can effectively dissipate the heat generated due to the increased functionalities.

A heat dissipating PCB refers to a functional PCB that lowers the temperature of the whole PCB by having a part exposed to the air or by spreading the heat generated in high density parts to the other parts.

A conventional heat dissipating PCB is made by inserting one or more metal layers in-between several layers or by adding a thick metal layer onto the inner layer (core) part, etc. In the heat dissipating PCB thus configured, the joining is performed using Prepreg (FR-4 epoxy resin), an electrical conductive adhesive (ECA) and/or an insulating resin, etc.

However, since the Prepreg, the electrical Conductive Adhesive, and the insulating resin are made of polymer materials, there is difficulty in effectively transferring heat to the heat dissipating layer. Consequently, there is a problem of low efficiency in heat dissipation.

### SUMMARY

An aspect of the present invention is to provide a printed circuit board (PCB) with high efficiency of heat dissipation and a method for manufacturing the printed circuit board by delivering the heat held in an insulating layer to a heat dissipating layer by forming a heat dissipating coating layer with high thermal conductivity on a heat dissipating layer.

One aspect of the invention provides a printed circuit board that includes an insulating layer, a circuit pattern formed on one side of the insulating layer, an inter-layer conductive part which joins with the insulating layer by passing through the insulating layer and which is electrically connected to the circuit pattern, a heat dissipating layer laminated on the other side of the insulating layer; and a heat dissipating coating layer which is interposed between the insulating layer and the heat dissipating layer and is connected with the inter-layer conductive part.

The heat dissipating layer may include an Al substrate, and the heat dissipating coating layer may include one or more material selected from a group consisting of gold, silver, and diamond-like carbon (DLC). Also, the heat dissipating coating layer may be coated on both sides of the heat dissipating layer.

Meanwhile, the printed circuit board may further include an additional insulating layer, an additional inter-layer conductive part which joins with the additional insulating layer by passing through the additional insulating layer and which is electrically connected to the circuit pattern, an additional heat dissipating coating layer which is interposed between the insulating layer and the additional insulating layer and which is connected with the additional inter-layer conductive part.

The additional heat dissipating coating layer may include one or more material selected from a group consisting of gold, silver, and diamond-like carbon (DLC), and the printed circuit board may further include an additional heat dissipating layer interposed between the insulating layer and the additional insulating layer.

The additional heat dissipating layer may include an Al substrate, and the additional heat dissipating coating layer may be coated on both sides of the additional heat dissipating layer.

The inter-layer conductive part may include paste bumps that are connected with the circuit patterns and hardened.

Meanwhile, another aspect of the invention provides a method of manufacturing a printed circuit board that includes forming a heat dissipating coating layer on the surface of a heat dissipating layer, forming circuit patterns on the surface of an insulating layer and forming an inter-layer conductive part which joins with the insulating layer by passing through the insulating layer and which is electrically connected with the circuit patterns, and laminating the insulating layer on the heat dissipating layer such that the inter-layer conductive part is connected with the heat dissipating coating layer.

The heat dissipating layer may include an Al substrate, and the heat dissipating coating layer may include one or more material selected from a group consisting of gold, silver, and diamond-like carbon (DLC). Also, the heat dissipating coating layer may be formed on both sides of the heat dissipating layer.

The laminating may include laminating an additional insulating layer on the insulating layer, and the additional insulating layer may include an additional inter-layer conductive part which joins with the additional insulating layer by passing through the additional insulating layer and which is electrically connected with the circuit pattern.

The method may further include interposing an additional heat dissipating coating layer connected with the additional inter-layer conductive part between the insulating layer and the additional insulating layer, before performing the laminating of the additional insulating layer on the insulating layer.

Also, the method may further include interposing an additional heat dissipating layer between the insulating layer and the additional insulating layer, before interposing the additional heat dissipating coating layer, where the additional heat dissipating coating layer may be formed on the surface of the additional heat dissipating layer.

Meanwhile, the forming of the circuit patterns and the inter-layer conductive part may include forming a paste bump on a metal layer and hardening the paste bump, laminating the insulating layer on the metal layer such that the paste bump passes through the insulating layer, and forming the circuit patterns by removing a part of the metal layer.

Additional aspects and advantages of the present invention will become apparent and more readily appreciated from the following description, including the appended drawings and claims, or may be learned by practice of the invention.

### BRIEF DESCRIPTION OF THE DRAWINGS

FIG. 1 is a cross-sectional view showing a printed circuit board according to an embodiment of the present invention.

FIG. 2 is a cross-sectional view showing a printed circuit board according to a second disclosed embodiment of the present invention.

FIG. 3 is a flowchart showing a method for manufacturing a printed circuit board according to an embodiment of the present invention.

### DETAILED DESCRIPTION

Embodiments of the printed circuit board according to the invention will be described below in more detail with reference to the accompanying drawings. In the description with reference to the accompanying drawings, those components are rendered the same reference number that are the same or are in correspondence, regardless of the figure number, and redundant explanations are omitted.

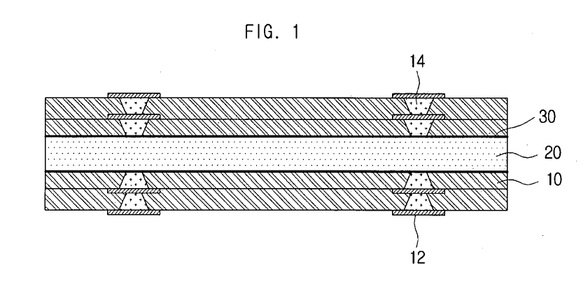

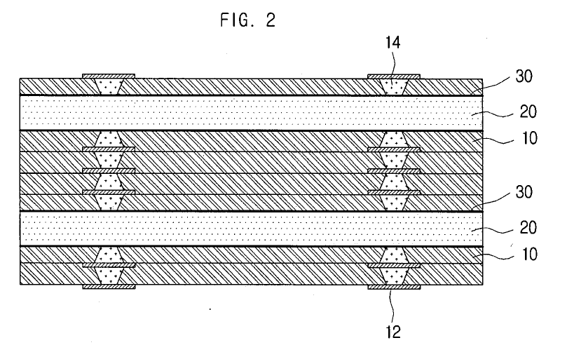

FIG. 1 is a cross-sectional view showing a printed circuit board according to an embodiment of the present invention, and FIG. 2 is a cross-sectional view showing a printed circuit board according to a second disclosed embodiment of the present invention. Referring to FIGS. 1 and 2, insulating layers 10, circuit patterns 12, bumps 14, a heat dissipating layer 20 and heat dissipating coating layers 30 are illustrated.

The insulating layers 10 may be made of Prepreg (PPG). The circuit patterns 12 and the bumps 14 may be formed in the insulating layer 10.

While Prepreg is presented as a material for the insulating layer 10 in the present embodiment, other materials may also be used, such as electro conductive adhesive and insulating resin, etc., according to design requirements.

The circuit patterns 12 may be formed on one side of an insulating layer 10. The circuit patterns 12 may be formed by printing circuit patterns on a carrier film and transferring it to the insulating layer 10. Also, the circuit patterns 12 may be formed by exposing and etching. As such, the circuit patterns 12 may be formed by a variety of methods. Meanwhile, the circuit patterns 12 serve as pathways through which electric signals may move, and the circuit patterns 12 may be made of conductive materials such as copper and silver. Of course, it is apparent that the circuit patterns 12 may be made of conductive paste other than that of copper or silver. The bumps 14 may be formed in predetermined positions of the circuit patterns 12.

A bump 14 may be formed in a predetermined position of the circuit patterns 12, and the position may be determined by the design according to the function of the printed circuit board. The bump 14 may be made of a conductive material such as copper and silver.

The bump 14 may be formed to pass through the insulating layer 10 in a direction along the plane of the insulating layer 10. The bump 14 may pass through the insulating layer 10 by forming the bump 14 on a carrier film together with the circuit patterns, stacking the carrier film on the insulating layer 10, and then pressing and transferring the bumps 14 from the carrier film to the insulating layer 10. Of course, various methods may be used for this, according to design requirements.

The bumps 14 may be connected to the circuit patterns 12 by passing through the insulating layer 10. The bumps 14 may serve as an inter-layer conductive part for connecting each layer electrically. In this way, a multi-layer printed circuit board may be formed.

While the bumps 14 made of conductive materials are presented as an inter-layer conductive part in this embodiment, other methods may also be used, such as using via-holes with conductive material coated on the inner wall of the via-holes. As such, the inter-layer conductive part may be formed by a variety of methods.

The heat dissipating layer 20 may perform a function of lowering the temperature of the PCB by holding the heat generated in the PCB and emitting the heat to the air or by delivering the heat to other parts of the PCB. The heat dissipating layer 20 may be made of materials high in thermal conductivity, such as aluminum (Al).

Meanwhile, the heat dissipating layer 20 may be selectively interposed between a plurality of insulating layers and may be stacked in order to improve the efficiency of the heat dissipation.

Greater thickness in the heat dissipating layer 20 may be advantageous, because the greater the thickness of the heat dissipating layer 20, the greater the capacity for holding the heat generated in the PCB. However, since the greater thickness of the heat dissipating layer 20 may cause the PCB to be thicker as well, the thickness of the insulating layers 10 may be reduced correspondingly. Thus, the efficiency of heat dissipation may be increased. The thickness of the heat dissipating layer 20 and the corresponding thickness of the insulating layers 10 may be determined according design requirements and conditions.

It may be expected that the efficiency of heat dissipation is increased by forming the heat dissipating layer 20 inside the PCB. However, because the basic component of Prepreg (FR-4 epoxy resin), electrical conductive adhesive, and insulating resin, etc., used as the insulating layer 10 is polymer material, it may be hard to deliver the heat to the heat dissipating layer 20. Thus, the efficiency of heat dissipation may not be particularly high. To improve this problem, the heat dissipating coating layers 30 may be formed on the surfaces of the heat dissipating layer 20 to increase the efficiency of heat dissipation.

The heat dissipating coating layer 30 may be interposed between the heat dissipating layer 20 and the insulating layer 10 that has absorbed the heat generated inside the PCB, and the heat dissipating coating layer 30 may improve the efficiency of heat dissipation by facilitating the heat dissipation between the two. Also, the heat dissipating coating layer 30 may be interposed between insulating layers to connect with the inter-layer conductive part. In this way, the heat dissipating coating layer 30 may facilitate the delivery of heat between insulating layers, and improve the efficiency of heat dissipation.

The heat dissipating coating layer 30 may made of a material including one or more material selected from a group consisting of gold, silver, and diamond-like carbon (DLC), which provide high thermal conductivity. Also, the heat dissipating coating layer 30 may be formed on one or both sides of the heat dissipating layer 20.

Meanwhile, the embodiments shown in FIGS. 1 and 2 are merely examples of the invention, and the number of insulating layers 10 and heat dissipating layers 20, and the shape of the inter-layer conductive part, etc., may be changed according to design requirements.

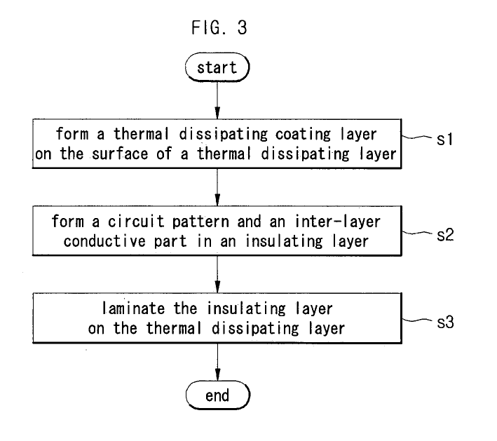

Next, referring to FIG. 3, a method for manufacturing a PCB according to another aspect of the invention will be described. FIG. 3 is a flowchart showing a method for manufacturing a printed circuit board according to an embodiment of the present invention.

Operation s1 is that of forming the heat dissipating coating layer 30 on the surface of the heat dissipating layer 20 before stacking the heat dissipating layer 20 on the insulating layer 10. For example, the heat dissipating coating layer 30 made of any one of gold, silver, and DLC (diamond like carbon), or a combination thereof, may be formed on both sides of the heat dissipating layer 20.

The heat dissipating coating layers 30 may be formed by a variety of methods such as those using PECVD (Plasma Enhanced Chemical Vapor Deposition), ion plating, laser ablation, and filtered vacuum arc, etc.

Among the described methods, an illustrative method using ion plating is as follows.

Ion plating is a method for obtaining a film having a cohesive power higher than that from the general vacuum plating method, by evaporating metal in a vacuum container and setting up a cathode (−) on the substrate (base material) and accelerating the ionization by means of glow discharge. Glow discharge is generally used for the ionizing. During the ionizing, a great variety of particles are generated. To improve the efficiency of the ion plating, it is necessary to enhance the ionization ratio (the proportion of the ionized atoms in the evaporated particle reaching a substrate).

For a vacuum container filled with Ar gas with a pressure of about 1×10⁻²˜1×10⁻³ Torr, where a negative (−) voltage of about −0.5˜2 kV with respect to the wall of the vacuum container is provided to the substrate, the glow discharge may take place between the substrate and its surroundings. Here, a strong dark space may be generated around the substrate. In this state, if a metal (or compound) is evaporated from an evaporation source, the evaporated atoms are ionized in the plasma of the glow discharge. The ionized and evaporated atoms are accelerated in the dark space with the gas ions, collide with the substrate and are coated on it. This is the Mattox method, and its ionization ratio is just 0.1˜0.3%.

Therefore, many methods for increasing the ionization ratio are presented, for example, \textcircled{1} the multi-cathode method, in which a hot cathode is set up in proximity to the substrate, so that the thermions generated collide with the evaporated atoms, resulting in ionization, \textcircled{2} the high-frequency wave excitation method, in which a high-frequency coil is set up on the evaporation source to promote the ionization by the high-frequency magnetic field, \textcircled{3} the induction heating method, in which ionization is promoted by a leakage flux as high frequencies are used to accelerate the evaporation source, \textcircled{4} the activated reactive evaporation (ARE) method, in which a gas that reacts easily with the evaporated atoms is provided in the evaporation space, and a stoichiometrically good compound is obtained by applying a discharge to the reactive evaporation for covering the compound, \textcircled{5} the cluster method, in which parts of a cluster of evaporated atoms are ionized and made to collide with the substrate, \textcircled{6} the hollow cathode discharge (HCD) method, in which materials are evaporated with a plasma electron beam using a special low-voltage high-current electron gun (HCD electron gun) and ionized at the same time, and \textcircled{7} the arc discharge method, in which the metal cooled by the arc discharge using the metal of the evaporation material as a cathode target is locally melted and simultaneously inonized.

As such, the ion plating as described in the above allows close adhesion between the film and the substrate and good compactness of the film. Also, special compound films may be obtained such as TiN, TiC, CrN, CrC, Al₂O₃, and SiO₂, etc. In addition, the substrate may not be deformed because the coating temperature is low.

Operation s2 is that of forming a circuit pattern and an inter-layer conductive part in the insulating layer 10.

For example, the circuit pattern and the inter-layer conductive part may be formed at the same time by forming conductive paste bumps 14 on a copper foil, hardening them, stacking the insulating layer 10 on the copper foil so that the paste bumps 14 pass through the insulating layer 10, and then removing parts of the copper foil.

Besides this, the inter-layer conductive part may be formed by forming via holes passing through the insulating layer 10 and then coating the inner wall of the via holes with conductive material.

Operation s3 is that of stacking the insulating layers 10 on the heat dissipating layer 20 to complete the manufacture of the PCB.

The PCB may be formed by sequentially laminating the insulating layers 10, which have the inter-layer conductive part and the circuit patterns 12, on the heat dissipating layer 20, which has the heat dissipating coating layer 30. Also, the PCB may be formed by stacking them preliminarily and then laminating collectively. The number of the insulating layers 10 and the number of the heat dissipating layer 20 may be varied according to design conditions and requirements.

By sequentially performing the operations s1 to s3, a PCB having a high efficiency of heat dissipation may be manufactured.

According to the present invention comprised as above, the heat contained in the insulating layer 10 may effectively be delivered to the heat dissipating layer 20 and the efficiency of heat dissipation may be improved by forming the heat dissipating coating layer 30 with high thermal conductivity on the heat dissipating layer 20.

While the present invention has been described with reference to particular embodiments, it is to be appreciated that various changes and modifications may be made by those skilled in the art without departing from the spirit and scope of the present invention, as defined by the appended claims and their equivalents.

What is claimed is:

1. A printed circuit board comprising:
an insulating layer;
a circuit pattern formed on one side of the insulating layer;
an inter-layer conductive part joining with the insulating layer by passing through the insulating layer, and electrically connected to the circuit pattern;
a heat dissipating layer laminated on the other side of the insulating layer; and
a heat dissipating coating layer interposed between the insulating layer and the heat dissipating layer, and connected with the inter-layer conductive part.

2. The printed circuit board of claim 1, wherein the heat dissipating layer comprises an Al substrate.

3. The printed circuit board of claim 1, wherein the heat dissipating coating layer comprises diamond-like carbon (DLC).

4. The printed circuit board of claim 1, wherein the heat dissipating coating layer is coated on both sides of the heat dissipating layer.

5. The printed circuit board of claim 1, further comprising:
an additional insulating layer;
an additional inter-layer conductive part joining with the additional insulating layer by passing through the additional insulating layer, and electrically connected to the circuit pattern;
an additional heat dissipating coating layer interposed between the insulating layer and the additional insulating layer and connected with the additional inter-layer conductive part.

6. The printed circuit board of claim 5, wherein the additional heat dissipating coating layer comprises diamond-like carbon (DLC).

7. The printed circuit board of claim 5, further comprising an additional heat dissipating layer interposed between the insulating layer and the additional insulating layer.

8. The printed circuit board of claim 7, wherein the additional heat dissipating layer comprises an Al substrate.

9. The printed circuit board of claim 7, wherein the additional heat dissipating coating layer is coated on both sides of the additional heat dissipating layer.

10. The printed circuit board of claim 1, wherein the inter-layer conductive part comprises a paste bump which is connected with the circuit patterns and hardened.

11. A method of manufacturing a printed circuit board, the method comprising:
forming a heat dissipating coating layer on the surface of a heat dissipating layer;
forming circuit patterns on the surface of an insulating layer, and forming an inter-layer conductive part joining with the insulating layer by passing through the insulating layer and electrically connected with the circuit patterns; and
laminating the insulating layer on the heat dissipating layer such that the inter-layer conductive part is connected with the heat dissipating coating layer.

12. The method of claim 11, wherein the heat dissipating layer comprises an Al substrate.

13. The method of claim 11, wherein the heat dissipating coating layer comprises diamond-like carbon (DLC).

14. The method of claim 11, wherein the heat dissipating coating layer is formed on both sides of the heat dissipating layer.

15. The method of claim 11, wherein the laminating comprises laminating an additional insulating layer on the insulating layer, and the additional insulating layer comprises an additional inter-layer conductive part joining with the additional insulating layer by passing through the additional insulating layer and electrically connected with the circuit pattern.

16. The method of claim 15, further comprising interposing an additional heat dissipating coating layer connected with the additional inter-layer conductive part between the insulating layer and the additional insulating layer before performing the laminating of the additional insulating layer on the insulating layer.

17. The method of claim 16, further comprising interposing an additional heat dissipating layer between the insulating layer and the additional insulating layer before interposing the additional heat dissipating coating layer, wherein the additional heat dissipating coating layer is formed on the surface of the additional heat dissipating layer.

18. The method of claim 11, wherein the forming of the circuit patterns and the inter-layer conductive part comprises:
forming a paste bump on a metal layer and hardening the paste bump;
laminating the insulating layer on the metal layer such that the paste bump passes through the insulating layer; and
forming the circuit patterns by removing a part of the metal layer.
